(19) United States
(12) Patent Application Publication
(10) Pub. No.: US 2022/0243993 A1
(43) Pub. Date: Aug. 4, 2022

(54) HEAT DISSIPATION APPARATUS

(71) Applicant: Jordan Ashton Garcia So, Mississauga (CA)

(72) Inventor: Jordan Ashton Garcia So, Mississauga (CA)

(21) Appl. No.: 17/167,145

(22) Filed: Feb. 4, 2021

(51) Int. Cl. F28D 15/04; F28D 15/02

(52) U.S. Cl. CPC F28D 15/046; H05K 7/20336; F28D 15/0233

(57) ABSTRACT

A heat dissipation apparatus that is configured to provide heat dissipation from electronic devices such as but not limited to a computer. The heat dissipation apparatus of the present invention is provided in three embodiments that include a vapor chamber, a heat pipe and a heat sink. The latter embodiment includes a support plate having an upper surface to which the core member of the present invention is secured. The heat pipe and vapor chamber embodiment of the present invention include a sealed housing creating an interior volume in which the core member is disposed. The core member of the present invention is manufactured from metal and is formed by three dimensional printing in a gyroid shape.

### FIELD OF THE INVENTION

The present invention relates generally to heat dissipation from electronic devices such as but not limited to computers, wherein the present invention provides a heat sink, vapor chamber or heat pipe design that is configured to have a greater surface area than conventional finned heat sinks and vapor chambers so as to provide an improved heat removal efficiency.

### BACKGROUND

As is known in the art, a heat sink is an object that disperses heat from another object. Heat sinks are commonly used in computers, but are also found in other electronics such as but not limited to DVD players and other household appliances. In computers, a heat sink is an attachment for a chip that prevents the chip from overheating and is very important for the proper performance of the computer. Conventional heat sinks have a thermal conductor that carries heat away from the CPU into fins that provide a large surface area for the heat to dissipate throughout the rest of the computer. The aforementioned facilitates cooling of both the heat sink and processor. It is quite common that a heat sink will have a fan adjacent thereto to move the heat away from the heat sink fins.

Heat sinks are usually made of metal, which serves as the thermal conductor that carries heat away from the electronics. One issue with metal heat sinks is that each metal has a different level of thermal conductivity. The higher the thermal conductivity of the metal, the more efficient it is at transferring heat. One of the most common metals used in heat sinks is aluminum. Aluminum has a thermal conductivity of 235 watts per Kelvin per meter (W/mK). Aluminum is inexpensive to produce and is lightweight avoiding other issue of physical stress on the computer board. Heavier materials such as copper have higher thermal conductivity but are more expensive and can place physical stress on the computer board. Regardless of the metal, the heat sink and its fin design are utilized to dissipate heat but the surface area of the fins and the type of metal utilized are ultimately a limitation for heat dissipation.

It is intended within the scope of the present invention to provide a heat sink assembly that provides a greater surface area than a conventional finned heat sink wherein the assembly is embodied both as a heat sink and/or vapor chamber that is operable to have a higher heat removal efficiency.

### SUMMARY OF THE INVENTION

It is the object of the present invention to provide a heat sink assembly configured to provide heat removal from an electronic device wherein the present invention that includes a body manufactured from a suitable metal such as but not limited to aluminum or copper.

Another object of the present invention is to provide a heat removal apparatus that is operable to dissipate heat from a device such as but not limited to a computer, wherein the body of the present invention includes a core member.

A further object of the present invention is to provide a heat sink assembly configured to provide heat removal from an electronic device wherein the core member is formed in a gyroid shape.

Still another object of the present invention is to provide a heat removal apparatus that is operable to dissipate heat from a device such as but not limited to a computer wherein the gyroid shape provides a greater surface area than a conventional finned heat sink.

An additional object of the present invention is to provide a heat sink assembly configured to provide heat removal from an electronic device wherein the gyroid shape facilitates a turbulent fluid flow so as to improve heat dissipation.

Yet a further object of the present invention is to provide a heat removal apparatus that is operable to dissipate heat from a device such as but not limited to a computer that is embodied as a heat sink, a vapor chamber or a heat pipe.

To the accomplishment of the above and related objects the present invention may be embodied in the form illustrated in the accompanying drawings. Attention is called to the fact that the drawings are illustrative only. Variations are contemplated as being a part of the present invention, limited only by the scope of the claims.

### BRIEF DESCRIPTION OF THE DRAWINGS

A more complete understanding of the present invention may be had by reference to the following Detailed Description and appended claims when taken in conjunction with the accompanying Drawings wherein:

FIG. 1 is an exposed view of a portion of a vapor chamber of the present invention; and

FIG. 2 is a cross-sectional of a vapor chamber of the present invention; and

FIG. 3 is an additional cross sectional of a vapor chamber of the present invention; and

FIG. 4 is a an exposed view of a heat pipe of the present invention; and

FIG. 5 is a cross sectional of a heat pipe of the present invention; and

FIG. 6 is an exemplary heat sink of the present invention.

### DETAILED DESCRIPTION

References now to the drawings submitted herewith, wherein various elements depicted therein are not necessarily drawn to scale and wherein through the views and figures like elements are referenced with identical reference numerals, there is illustrated a heat dissipation apparatus 100 constructed according to the principles of the present invention.

An embodiment of the present invention is discussed herein with reference to the figures submitted herewith. Those skilled in the art will understand that the detailed description herein with respect to these figures is for explanatory purposes and that it is contemplated within the scope of the present invention that alternative embodiments are plausible. By way of example but not by way of limitation, those having skill in the art in light of the present teachings of the present invention will recognize a plurality of alternate and suitable approaches dependent upon the needs of the particular application to implement the functionality of any given detail described herein, beyond that of the particular implementation choices in the embodiment described herein. Various modifications and embodiments are within the scope of the present invention.

It is to be further understood that the present invention is not limited to the particular methodology, materials, uses and applications described herein, as these may vary. Furthermore, it is also to be understood that the terminology used herein is used for the purpose of describing particular embodiments only, and is not intended to limit the scope of the present invention. It must be noted that as used herein and in the claims, the singular forms “a”, “an” and “the” include the plural reference unless the context clearly dictates otherwise. Thus, for example, a reference to “an element” is a reference to one or more elements and includes equivalents thereof known to those skilled in the art. All conjunctions used are to be understood in the most inclusive sense possible. Thus, the word “or” should be understood as having the definition of a logical “or” rather than that of a logical “exclusive or” unless the context clearly necessitates otherwise. Structures described herein are to be understood also to refer to functional equivalents of such structures. Language that may be construed to express approximation should be so understood unless the context clearly dictates otherwise.

References to “one embodiment”, “an embodiment”, “exemplary embodiments”, and the like may indicate that the embodiment(s) of the invention so described may include a particular feature, structure or characteristic, but not every embodiment necessarily includes the particular feature, structure or characteristic.

Now referring to the Figures submitted herewith, the heat dissipation apparatus 100 can be embodied as a heat sink, a vapor chamber or a heat pipe. Furthermore a system deploying a combination of any of the three aforementioned embodiments could further be deployed. Thermal engineers design cooling solutions for various electronic devices such as but not limited to computers. The heat generated by these electronic devices must be dissipated in order to ensure proper operation of the device. For some electronic devices a heat sink may provide sufficient heat dissipation but for other devices a two-phase cooling solution is required. Two common two-phase cooling solutions that are utilized are heat pipes and vapor chambers. The general operating principles of the heat pipe and vapor chamber are the same. Conventional technology deploys a wick structure to the inside walls of an enclosure, i.e., a heat pipe or vapor chamber. This internal wick structure is often embodied as mesh screens or grooves. Liquid is disposed within the heat pipe or vapor chamber, typically being vacuum sealed therein, and the wick structure distributes the liquid through the heat pipe or vapor chamber. When a portion of the heat pipe or vapor chamber is heated through exposure to an element of an electronic apparatus, the liquid vaporizes and moves to an area of lower pressure within the heat pipe or vapor chamber where it cools thus returning to a liquid form and moves back towards the heat source.

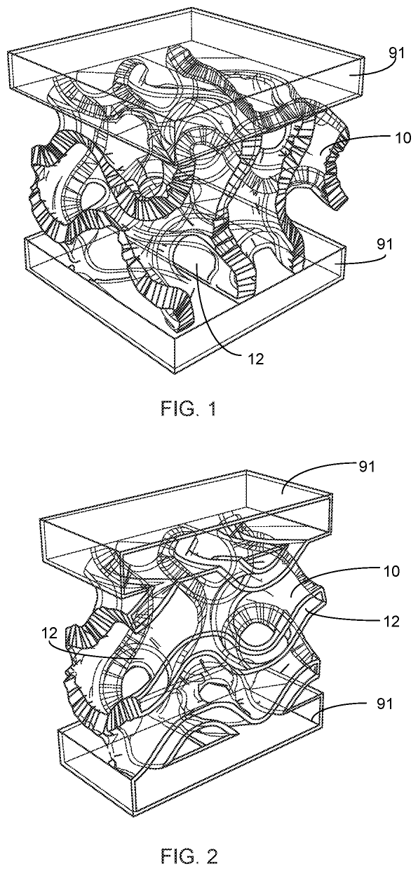

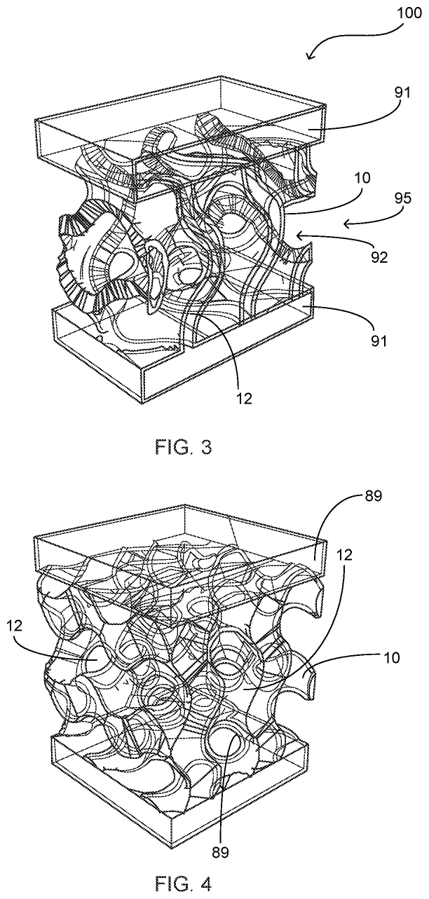

The surface area of the wick structure controls the efficiency and heat dissipation capabilities of heat pipes and vapor chambers. Similarly, for conventional heat sinks, the surface area provided by the conventional finned designed provides the heat dissipation rate. An improvement in the surface area within the same sized device would lead to a greater heat dissipation rate. The present invention provides a heat dissipation apparatus 100 that is embodied as a heat sink 85, a heat pipe 90 and a vapor chamber 95 all employing a core member 10 wherein the core member 10 provides maximization of surface area available within a defined size. Referring in particular to FIGS. 1 through 3, the vapor chamber 95 embodiment is illustrated therein. The vapor chamber 95 includes outer housing 91 that is manufactured from a suitable material such as but not limited to aluminum or copper. The vapor chamber housing 91 can be manufactured in various sizes and shapes in order to be operably coupled to a desired electronic device. The interior volume 92 of the vapor chamber 95 has disposed therein the core member 10 that is further discussed herein. It should be understood within the scope of the present invention that the vapor chamber 95 is a completely sealed unit and has a liquid disposed within the interior volume 92 thereof.

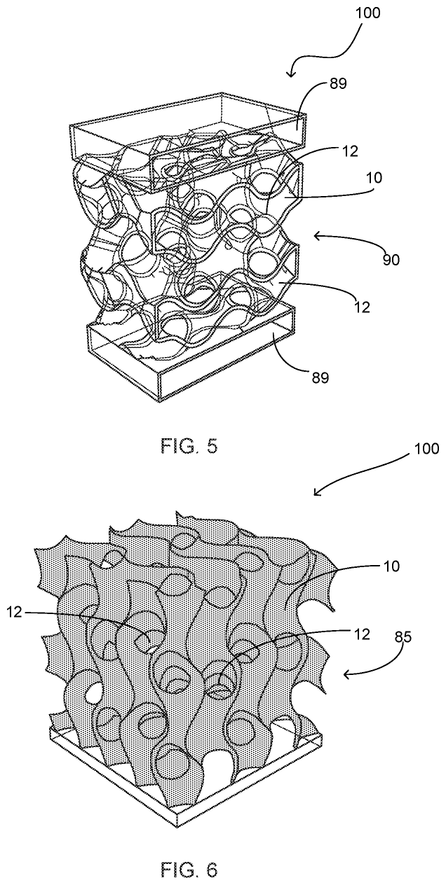

The heat pipe 90 of the present invention is illustrated in sectional views herein in FIGS. 4 and 5. The heat pipe 90 includes outer housing 89 that is tubular in shape and is manufactured from a suitable metal. The outer housing 89 defines the interior volume 88 wherein the core member 10 is disposed therein. It should be understood within the scope of the present invention that the heat pipe 90 could be manufactured in alternate lengths and diameters in order to achieve the desired heat dissipation.

Illustrated herein in FIG. 6 is the heat sink 85 of the present invention. The heat sink 85 includes a support plate 82 that is planar in manner and operable to provide a support structure for the core member 10. While the heat sink 85 is illustrated herein as being cube shaped, it should be understood within the scope of the present invention that the heat sink 85 could be provided in alternate shapes and sizes.

The core member 10 of the heat dissipation apparatus 100 is configured to provide a maximum amount of surface area per cubic inch of space. The core member 10 is deployed in all embodiments of the heat dissipation apparatus 100 and the configuration thereof further provides a turbulent flow of either a liquid or air. The core member 10 is manufactured from a suitable metal such as but not limited to aluminum or copper. The construction of the core member 10 is achieved utilizing three dimensional printing manufacturing and is gyroid in shape. The gyroid shape of the core member 10 provides both the desired increase of surface area per cubic inch and the turbulent fluid flow so as to maximize the heat dissipation rate of the heat dissipation apparatus 100. The gyroid shape is the unique non-trivial embedded member of the associate family of the Schwarz P and D surfaces. The angle of association with respect to the Schwarz D surface is approximately thirty eight degrees. The gyroid shape of the core member 10 separates space into two oppositely congruent labyrinths of passages 12. The aforementioned shape of the core member 10 and the passages 12 thereof provide a gyration of any fluid or air traversing therethrough. This turbulence of the fluid flow provides an increase in the rate of heat dissipation. It should be understood within the scope of the present invention that the core member 10 could be altered in shape but yet maintain triply periodic gyroid like structures and achieve the desired results discussed herein.

In the preceding detailed description, reference has been made to the accompanying drawings that form a part hereof, and in which are shown by way of illustration specific embodiments in which the invention may be practiced. These embodiments, and certain variants thereof, have been described in sufficient detail to enable those skilled in the art to practice the invention. It is to be understood that other suitable embodiments may be utilized and that logical changes may be made without departing from the spirit or scope of the invention. The description may omit certain information known to those skilled in the art. The preceding description is, therefore, not intended to be limited to the specific forms set forth herein, but on the contrary, it is intended to cover such alternatives, modifications, and equivalents, as can be reasonably included within the spirit and scope of the invention.

What is claimed is:

1. A heat dissipation apparatus configured to facilitate heat removal generated by an electronic device wherein the heat dissipation apparatus comprises:
a housing, said housing forming an interior volume, said housing being manufactured from metal, said housing being completely sealed;
a core member, said core member disposed within the interior volume of said housing, said core member being manufactured from a metal, said core member being sized so as to substantially fill the interior volume of said housing, said core member being gyroid in shape.

2. The heat dissipation apparatus as recited in claim 1, wherein the core member 10 further includes a plurality of passages, wherein said passages create a turbulent flow of liquid disposed within the heat dissipation apparatus.

3. The heat dissipation apparatus as recited in claim 2, wherein the heat dissipation apparatus is manufactured in an embodiment selected from a group consisting of one of the following: a heat pipe or a vapor chamber.

4. A heat dissipation apparatus configured to facilitate heat removal from an electronic device wherein the heat dissipation apparatus comprises:
a support plate, said support plate being manufactured from metal, said support plate being planar in manner, said support plate having an upper surface;
a core member, said core member being superposed said upper surface of said support plate, said core member being manufactured from a metal, said core member operable to cover an entire surface area of said upper surface of said support plate.

5. The heat dissipation apparatus as recited in claim 4, wherein the heat dissipation apparatus is a heat sink assembly.
